(19) United States
(12) Patent Application Publication
(10) Pub. No.: US 2014/0060620 A1
(43) Pub. Date: Mar. 6, 2014

(54) SOLAR PHOTOVOLTAIC PANEL COOLING SYSTEM AND METHOD

(71) Applicant: Tennessee Valley Authority, Knoxville, TN (US)

(72) Inventor: Neil Vincent PLACER, Chattanooga, TN (US)

(73) Assignee: Tennessee Valley Authority, Knoxville, TN (US)

(21) Appl. No.: 14/015,491

(22) Filed: Aug. 30, 2013

Related U.S. Application Data
(60) Provisional application No. 61/695,921, filed on Aug. 31, 2012.

(51) Int. Cl. H01L 31/052

(52) U.S. Cl. CPC H01L 31/0521
USPC 136/246

(57) ABSTRACT

A solar photovoltaic panel system which has a thermal sink and a panel mounting structure is provided. The panel mounting structure contains a water flow section. The water flow section includes an inflow section and an outflow section. A solar photovoltaic panel is mounted between the inflow section and the outflow section. A water supply system is connected to the panel mounting structure to provide water on a top surface of the solar photovoltaic panel. The water provided from the thermal sink is returned to the thermal sink after flowing on the top surface of the solar photovoltaic panel.

### BACKGROUND OF THE INVENTION

1. Field of the Invention

This invention relates to cooling solar photovoltaic (PV) panels (cool solar), and in particular to systems and methods for water-cooling solar PV panels based on a water supply system which includes a ram pump, and which provides water from a water thermal sink for treating solar PV panels with water to cool, clean and increase the efficiency of the solar PV panel system.

2. Description of Related Art

Solar photovoltaic systems, which rely on sunlight striking panels of photovoltaic elements to produce electricity, have been known for some time.

The use of such solar photovoltaic panels has been known to involve several problems. One problem relates to applied solar energy resulting in heating the photovoltaic panel to an increased temperature, which results in a decrease in the photoelectric conversion efficiency. Another problem has been the deposition of particulate matter (e.g., dust, debris, etc.) on the solar photovoltaic panels, which may also result in adverse effects, such as a decrease in efficiency of the photovoltaic panels.

One attempt to address the foregoing problems is described in EP 2012366, which describes the use of various closed loop system designs that utilize valves, controls, and coolant liquids to increase photoelectric conversion efficiency. Although these system designs effectively utilize the thermal energy extracted from the PV panels for other applications, such as to assist in heating a water heater, this benefit comes with added costs and complexity in system design and life-cycle maintenance.

Another approach for addressing the problems via an open loop system is described in JP 07-038131, which describes the use of a tap water pipe installed above a solar panel, and a valve which is opened to cool down the solar panel by application of the tap water thereto when the solar panel cell exceeds a certain temperature; the valve is closed to stop the tap water flow when the solar cell falls below a certain temperature. It is noted that the system also removes dust.

JP 2000-261021 describes additional open loop systems. The cooling of a solar battery constituting a silicon semiconductor is detailed, in one embodiment, by using water from a mountain source (e.g., a mountain spring) for cooling when the voltage is decreased due to an increase of temperature. According to a preferred embodiment, a radiator plate which conducts heat is mounted on the backside of a solar battery cell, and a solar battery module is mounted on the inner side of an inclined gutter, and a bar-shaped sprinkling device is arranged at the upper part of the gutter, wherein cooling by application of water on the underside of the photovoltaic panel is achieved. According to another embodiment, water flow may be applied to the surface of an inclined conventional solar battery module.

The foregoing attempts to address the problem of heating of photovoltaic panels and the loss of efficiency resulting therefrom have not been completely successful in satisfactorily resolving all problems relating to the heating of solar panels and the loss of efficiency resulting therefrom. For instance, the systems described above require increased system design complexity, additional required structure (e.g., linkage to water sources, coolant loops, piping, valves, electromechanical controls, radiator plates, etc.), and increase routine maintenance requirements for the additional required structure.

With respect to the open loop systems cited, a lack of practical solutions exist for obtaining and providing water to the solar panel, and subsequent treatment/handling of the water after application to the panel.

There has been a continuing need for a system that reduces costs and complexity, and which has great flexibility to control water flow patterns to increase capture of solar irradiation via an adjustable water refraction layer.

It has now been determined that a system is required that uses a free and abundant source of thermal transfer so that special coolant liquids are not required, and wherein supplying of liquids may be done without the use of electrical energy, valves, or controls to eliminate problems associated with reducing water flow rates to optimize energy and/or cost savings.

### SUMMARY OF THE INVENTION

In order to improve electrical performance, to reduce operations and maintenance (O&M) costs, and to extend the lifetime of solar PV panels, the panels are water cooled by creating a water layer on the solar PV panels.

The water layer on the solar PV panels reduces the operating temperature of the solar PV panels, constantly removes dust or prevents dust from being accumulated on the solar PV panels, removes other foreign particles from the surface of the solar PV panel and collects additional solar irradiation due to light refraction. As a result, inter alia, electrical performance of the solar PV panels can be improved. In addition, the water cooling reduces thermal cycling which results in extending the lifetime of the solar PV panels. However, water flow patterns different from a thin continuous flowing water layer may be desired depending on conditions such as temperature of the solar PV panel, amount of dust or other particles on the surface of the solar PV panel, or the angle at which the sun light arrives at the solar PV panel.

The application of a water layer on the solar PV panel leads to a reduction of O&M costs because separate operations for removing dust and other foreign particles is almost never required.

The cool solar concept is particularly well suited for geographic regions where sufficient water constituting a large heat sink is available.

Another important aspect of an exemplary embodiment of the invention is the water supply system, which in one preferred embodiment is implemented as an open loop water-cooling system. The open loop system reduces cost and complexity of the water supply system.

In one embodiment, the water supply system is preferably based on a ram pump. A ram pump is powered by readily available hydropower, and does not require electrical power. Utilizing a ram pump avoids consuming electrical power from the solar PV panels or from any other electrical power source. As a result, costs for electricity to operate a water pump can be eliminated, and the electrical efficiency of the solar power providing facility, in which the solar PV panels are installed, can be increased. The use of a water supply system based on a ram pump eliminates concerns for pumping use time and the need to control the water source. In other words, a ram pump does not create a net loss of energy production from the pumping operation.

Since the amount of water taken out of a water source, such as, for example, a river or a lake, is significantly smaller than the amount of water contained in the water source, the water of the water source remains substantially thermally constant; that is, the water used for water-cooling the solar PV panels and returned to the water source does not significantly change the temperature of the water source.

The use of filters in the water supply system protects the water supply system and solar cooling system from being clogged or polluted and the water source from being contaminated when the water is returned to the water source after being used for cooling the solar PV panels.

### BRIEF DESCRIPTION OF THE DRAWINGS

The above and/or other aspects of the present invention will be more apparent by describing in detail exemplary embodiments thereof with reference to the attached drawings, in which:

FIG. 1 is a schematic diagram illustrating the water flow in a solar photovoltaic panel system according to a general embodiment of the present invention.

FIG. 2 is a schematic diagram illustrating a water cooling system of solar PV panels from a first view angle according to an exemplary embodiment of the present invention.

FIG. 3 is a schematic diagram illustrating the water cooling system of solar PV panels from a second view angle according to another exemplary embodiment of the present invention.

FIG. 4 is a schematic diagram illustrating a water cooling system of solar PV panels from the first view angle according to the exemplary embodiment of the present invention illustrated in FIG. 3.

FIG. 5 is a diagram illustrating a water collection tray.

FIG. 6 is a schematic diagram illustrating a panel mounting structure from a first view angle according to another exemplary embodiment.

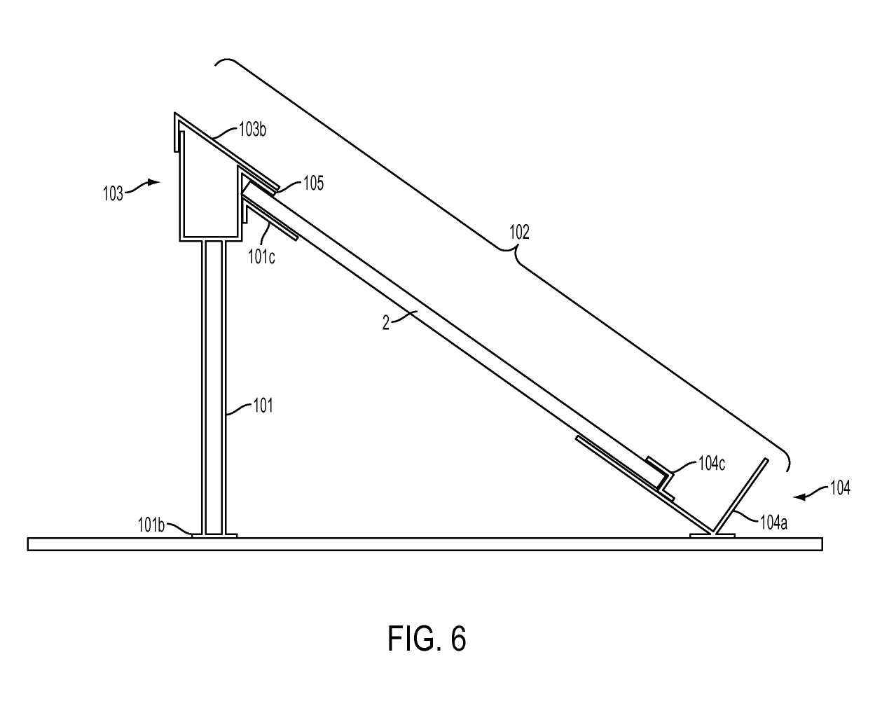

FIG. 7 is a schematic diagram illustrating a panel mounting structure from a second view angle according to the exemplary embodiment shown in FIG. 6.

FIG. 8 is a schematic diagram illustrating a water cooling system of solar PV panels from a first view angle according to a further exemplary embodiment of the present invention.

FIG. 9 is a schematic diagram illustrating a panel mounting structure from a second view angle according to the further exemplary embodiment shown in FIG. 8.

### DETAILED DESCRIPTION OF EXEMPLARY EMBODIMENTS

Hereinafter, exemplary embodiments of the present invention are described in greater detail with reference to the accompanying drawings, in which exemplary embodiments of the invention are shown.

In the following description, the same reference numerals are used for the same elements when they are depicted in different drawings. The features defined in the description, such as detailed construction and elements, are provided to assist in a comprehensive understanding of the invention. Thus, it is apparent that various embodiments of the present invention can be carried out without those specifically defined features. Also, functions or elements known in the related art are not described in detail since they would obscure the invention with unnecessary detail.

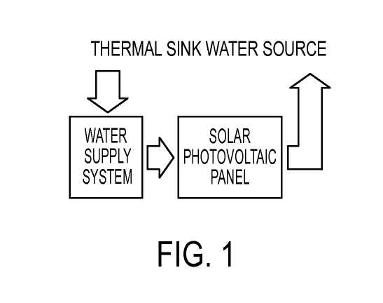

FIG. 1 is a schematic diagram illustrating the water flow in a solar photovoltaic panel system according to a general embodiment of the present invention. As shown in FIG. 1, water flows in an open loop system from a thermal sink water source through a water supply system to a solar photovoltaic panel. From the solar photovoltaic panel, the water flows back to the thermal sink water source.

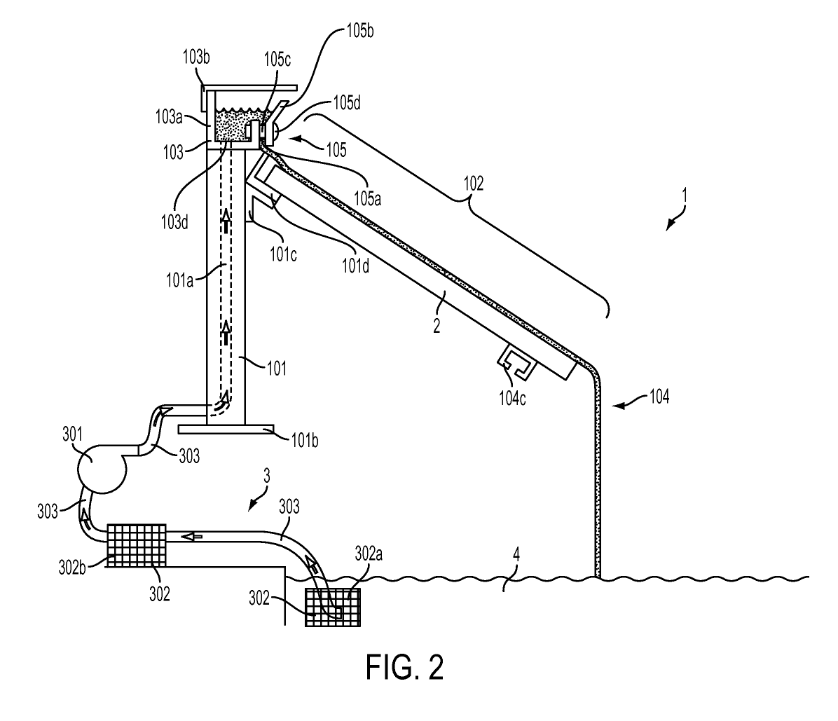

FIG. 2 is a diagram illustrating a water cooling system of solar PV panels from a first view angle according to an exemplary embodiment of the present invention. The water cooling system of solar PV panels of FIG. 2 includes a panel mounting structure 1, a first solar PV panel 2a, a second solar PV panel 2b and a water supply system 3.

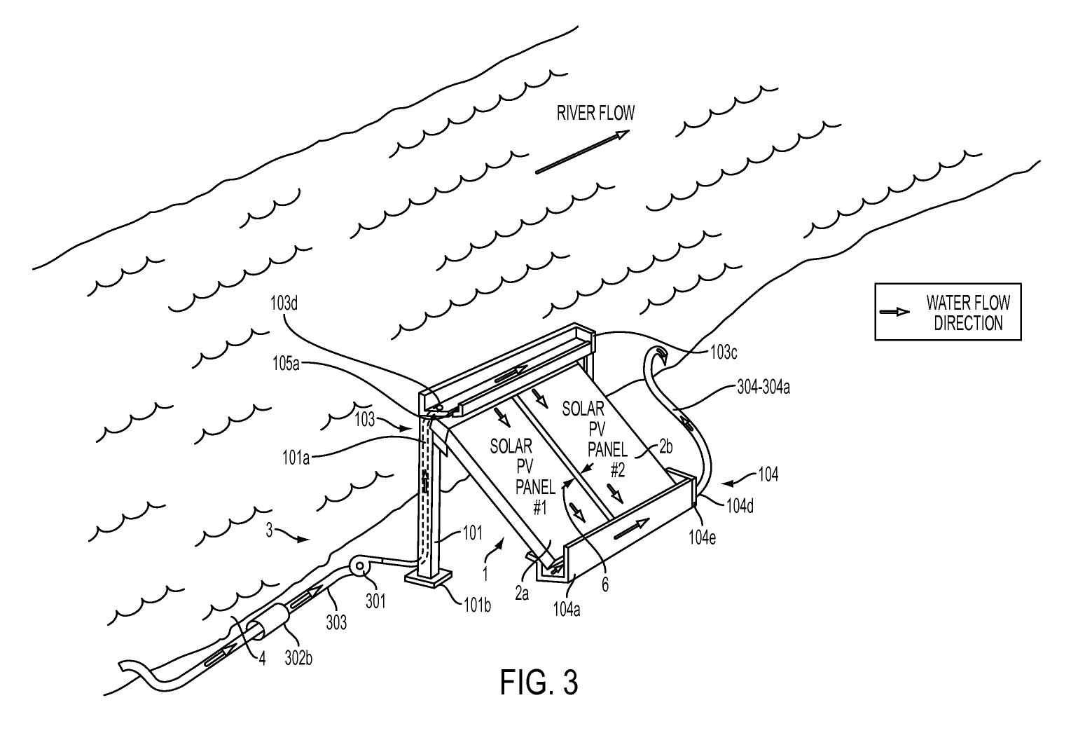

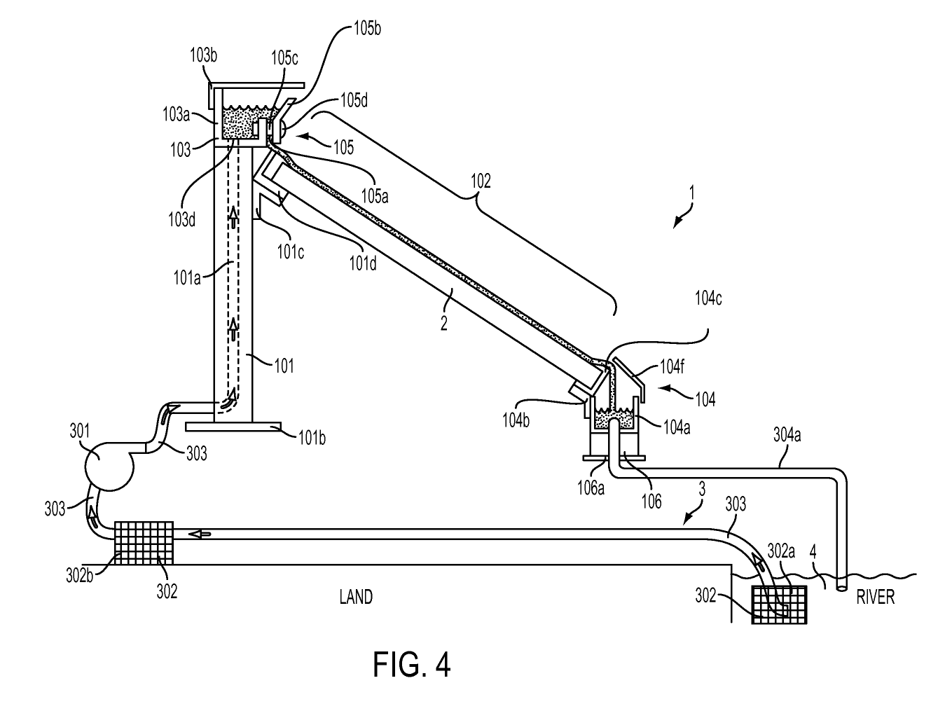

The panel mounting structure 1, as shown in FIG. 2, contains an inflow section 103 and an outflow section 104. The panel mounting structure 1 further includes a base plate 101b which may be provided at a same elevation as the outflow section 104, as shown in FIG. 2. In one exemplary embodiment, the inflow section 103 and the outflow section 104 may have a same elevation. In another exemplary embodiment, the inflow section 103 may have an elevation that is higher than the elevation of the outflow section 104, as shown in FIGS. 3 and 4.

The vertical structure 101 is installed on the base plate 101b and the inflow section 103 is provided on top of the vertical structure 101. The vertical structure 101 may include multiple vertical structure elements and the base plate 101b may include multiple base plates. The inflow section 103 includes an inflow water channel structure 103a and the outflow section 104 includes a panel mounting structure 104c. Water from the thermal sink, i.e., from the water source 4, is provided by a water supply system 3 to the inflow section 103, flows on the surface of the at least one solar PV panel 2 and is directly returned to the thermal sink via the outflow section 104. No further pipes or other structural elements are required to return the water to the thermal sink.

A system which provides water from a thermal sink, returns the water to the thermal sink, and does not “reuse” or provide the same water again to the system, is called an open loop thermal exchange system. Such an open loop thermal exchange system is used in the exemplary embodiment illustrated in FIG. 2 and also in the exemplary embodiment illustrated in FIGS. 3 and 4 discussed below.

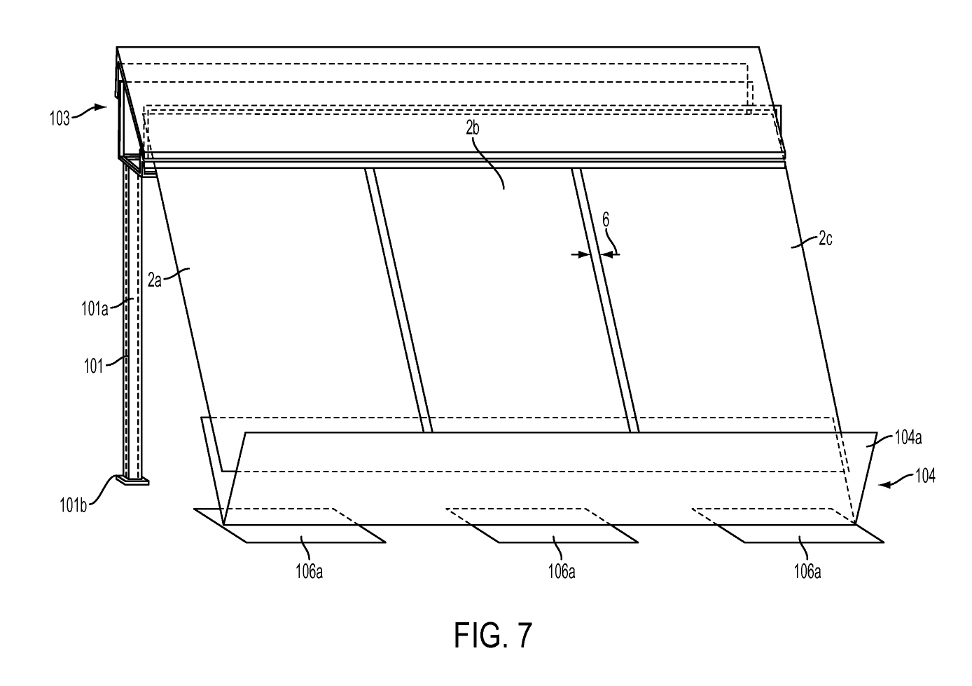

The inflow section 103 may be connected to the vertical structure 101 and the outflow section 104 may be connected to another vertical structure 106 which may contain another base plate 106a. The other base plate 106a may include multiple base plates which may also be installed without the other vertical structure 106, as shown in FIG. 7.

A solar PV panel 2 is mounted between the inflow section 103 and the outflow section 104. For example, a first mounting bracket 101c may be attached to an upper portion of the vertical structure 101 and an inflow panel mounting structure 101d may be attached to the first mounting bracket 101c. Similarly, a panel mounting section 104c may be attached to the solar PV panel 2, as illustrated in FIG. 2.

FIG. 3 is a schematic diagram illustrating the water cooling system of solar PV panels from a second view angle according to another exemplary embodiment of the present invention. FIG. 4 is a schematic diagram illustrating a water cooling system of solar PV panels from the first view angle according to another exemplary embodiment of the present invention illustrated in FIG. 3.

In this exemplary embodiment, a second mounting bracket 104b may be attached to an outflow water channel structure 104a and the panel mounting section 104c may be attached to a second mounting bracket 104b.

The outflow water channel structure (104a) may also be attached to the vertical structure 106 and the second mounting bracket 104b may be attached to the vertical structure 106 instead of being attached to the outflow water channel structure 104a.

In this exemplary embodiment, one end of the solar PV panel 2 is mounted in the inflow panel mounting structure 101d; the other end of the solar PV panel 2 is mounted in the panel mounting section 104c.

The inflow section 103 of the panel mounting structure 1 contains an inflow water channel structure 103a. The water supply system 3 provides water to panel mounting structure 1 via a pipe 303 which may be connected to an internal pipe 101a installed in the vertical structure 101 of the panel mounting structure. In a further exemplary embodiment, the pipe 303 may include a plurality of pipes 303 and may be connected to a system of a plurality of internal or external pipes installed in or on the panel mounting structure 1.

The internal pipe 101a may be connected to a water inlet 103d which is connected to the inflow water channel structure 103a. It may be connected to a bottom or a side of the inflow water channel structure 103a to provide water to the inflow water channel structure 103a.

The inflow section 103 further contains an inflow channel debris guard 103b which is preferably provided on top of the inflow water channel structure 103a or otherwise integrated in the inflow water channel structure 103a. The inflow water channel structure 103a may further include an inflow end cap 103c. The inflow end cap 103c may include multiple end caps provided at end portions of the inflow water channel structure 103a.

A water flow control structure 105 is provided which controls a flow of water on a top surface of the solar PV panel 2, 2a, 2b, 2c. The water flow control structure 105 provides a water flow pattern which may be a continuous and steady water layer having an adjustable thickness. Other water flow patterns may be generated by the water flow control structure 105 such as a discontinuous water flow pattern.

The water flow control structure 105 may contain a water flow bracket 105b, a spacer 105c and a fastener 105d. The water flow bracket 105b, which may be adjustable, may be connected to the inflow water channel structure 103a via the fastener 105d and the spacer 105c. A water outlet 105a is formed between the inflow water channel structure 103a and the water flow bracket 105b. The size of the water outlet 105a may be adjusted by moving the water flow bracket 105b relative to the inflow water channel structure 103a using fastener 105d. However, any other structure that allows providing a controlled and adjustable flow of water on the top surface of the solar PV panel 2, 2a, 2b, 2c may also be used.

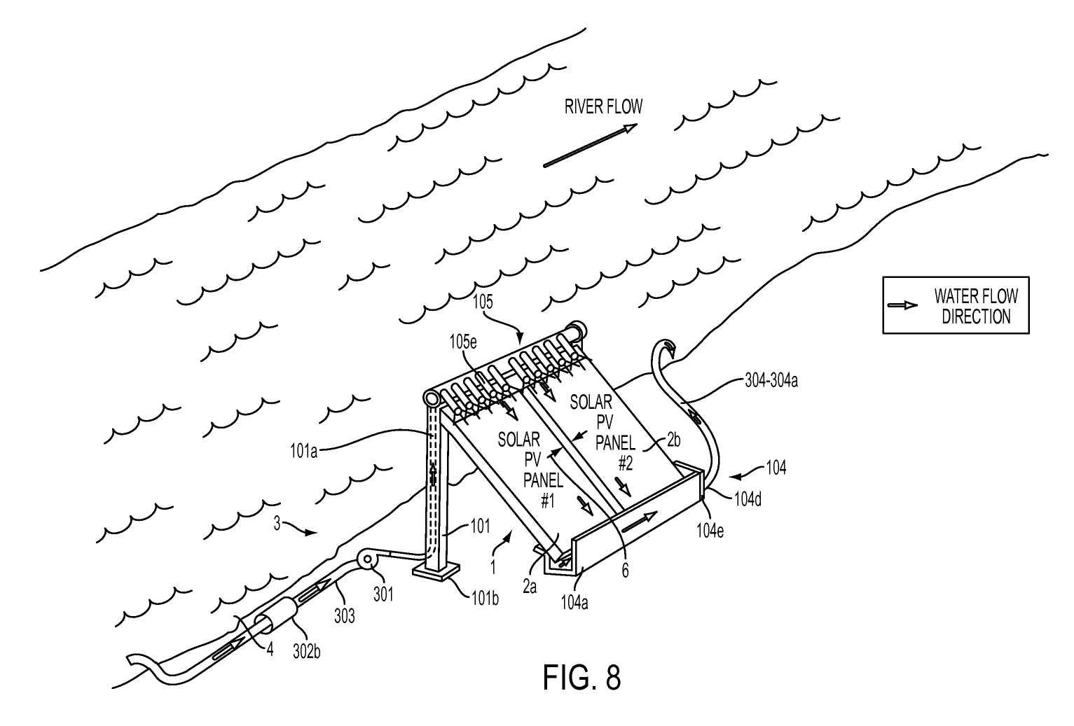

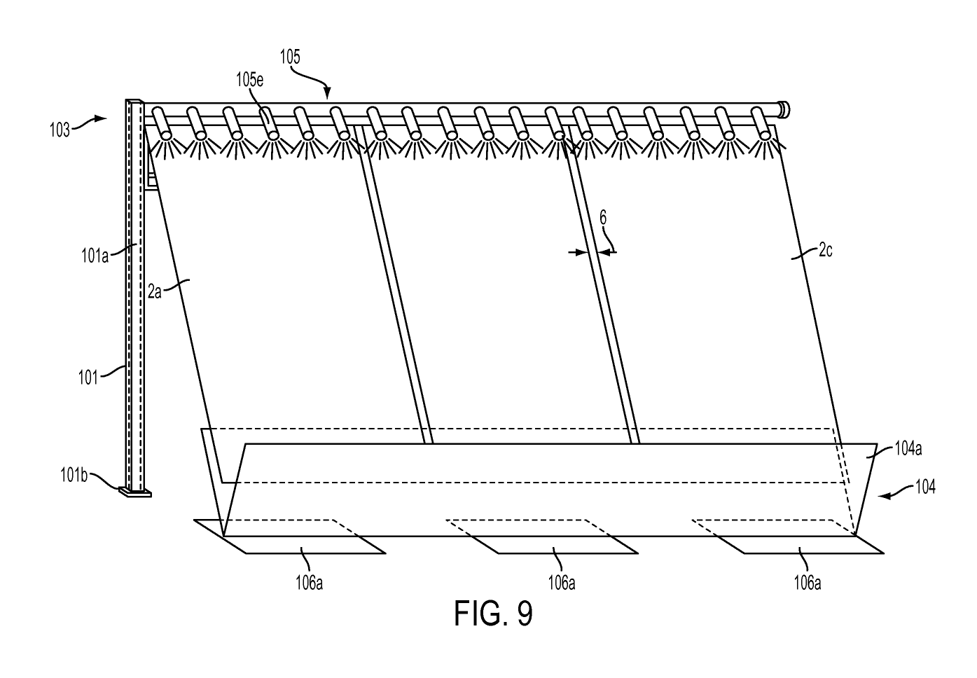

In a further exemplary embodiment, the water flow control structure 105 may include a nozzle 105e, as shown in FIGS. 8 and 9 which sprays water on a surface of the solar PV panel 2, 2a, 2b, 2c. The nozzle 105e may be implemented as multiple nozzles, as shown in FIGS. 8 and 9.

In another exemplary embodiment, the operation of the water flow control structure 105 may be controlled by an electric step motor (not shown) or by another control device which may be controlled by a computer or control processor (not shown). For example, the electric step motor may control the movement of the adjustable water flow bracket 105b or a controllable valve (not shown) which may adjust the amount of water sprayed by the nozzle.

An overflow outlet may be provided to the inflow water channel structure 103a to regulate the water level in the inflow water channel structure 103a if the amount of water provided by the water inlet 103d is higher than the amount of water flowing through the water outlet 105a. For example, the water flow bracket 105b may have a height that is lower than the highest walls of the inflow water channel structure 103a and of the inflow end caps 103c. As a result, when the water level in the inflow water channel structure 103a reaches the height of the water flow bracket 105b, the water flows over the water flow bracket 105b to the solar PV panel 2. Thereby, the water flow bracket 105b also forms a built in overflow outlet.

The outflow section 104 may further comprise an outflow channel debris guard 104f and outflow end caps 104e.

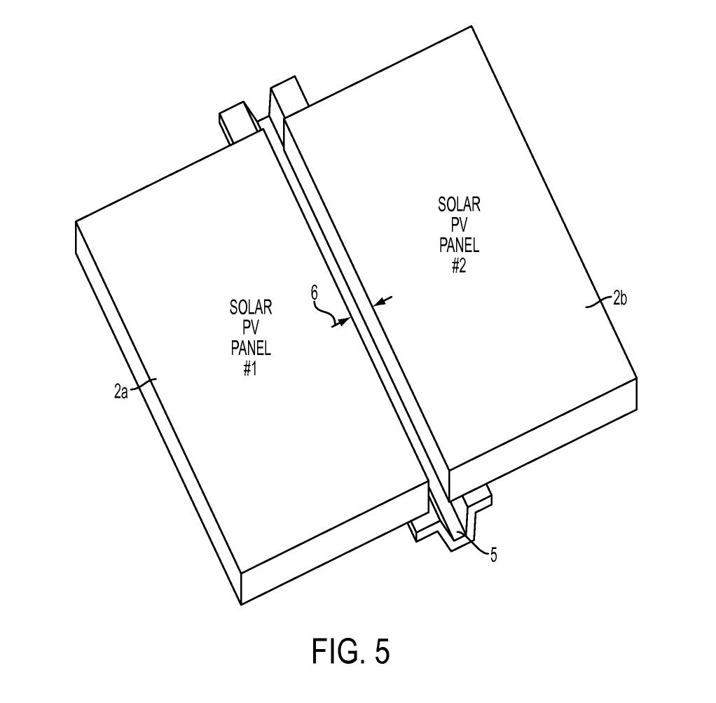

FIG. 5 is a diagram illustrating a water collection tray. A water collection tray 5 may be mounted between two adjacent solar PV panels 2a and 2b and prevents the solar PV panel system from water loss.

The water collection tray 5 may connect the inflow water channel structure 103a of the inflow section 103 with the outflow water channel structure 104a of the outflow section 104.

The water collection tray 5 may bridge a gap 6 between the two adjacent solar PV panels 2a and 2b which must be mounted with a gap 6 in between due to thermal expansion.

In addition, a water collection tray 5 may be mounted on a side of a solar PV panel 2, 2a or 2b which is not adjacent to a side of another solar PV panel and which is also not adjacent to the inflow water channel structure 103a of the inflow section 103 and to the outflow water channel structure 104a of the outflow section 104.

One exemplary water supply system 3, as shown in FIGS. 2-4 and 8, contains a pump 301, such as a ram pump. A ram pump uses hydropower, i.e., energy associated with the movement of the water, pressure in the water, or height of the water relative to a reference point, instead of using electrical power. However, any other pump or water delivery method may also be used in the water supply system. For example, in a particular exemplary embodiment, the water supply system 3 may be operated by an electric pump which consumes only a very limited amount of electrical energy. In addition, the electric pump, or any other element of the solar PV panel system, such as valves or motors which adjust the position of the solar PV panel 2, 2a, 2b, 2c, and valves and controls that adjust the water flow, may be operated without consuming electrical energy from the solar PV panel 2, 2a, 2b, 2c.

The structure of the water-cooling system should be mounted with a downward slope with a highest elevation at the water inlet 103d. The water supply system 3 further includes a filter 302 which may include a primary filter 302a and a secondary filter 302b. The primary filter 302a may be installed under water in the water source 4, as shown in FIG. 4. The secondary filter 302b may be installed between the ram pump 301 and the primary filter 302a.

The system further includes at least one return water channel 304. The return water channel 304 may be implemented as an open trough system and/or as a return pipe 304a. A first end of the return water channel 304 may be connected to the outflow section outlet 104d and a second end of the return water channel 304 may be connected to the water source 4 in order to return the water to the water source 4. An outflow end cap 104e may be provided at an end of the outflow water channel structure 104a. The outflow end cap 104e may include multiple outflow end caps 104e provided at multiple ends of the outflow channel structure 104a. The return pipe 304a may be connected to the outflow end cap 104e.

Water source 4 is a thermal sink, i.e., a substantially thermally constant heat sink. In other words, the use of some water of the water source 4 to cool the solar PV panels does not significantly change the temperature of the water in the water source 4 when the used water is returned. Water source 4 may be any water source that is thermally constant, such as a river, a lake, a marina or an ocean. The thermal sink is a readily available and abundant source of thermal transfer and no specific coolant liquid other than the water from the thermal sink is required.

The water flowing through the water outlet 105a may create a continuous and steady water layer on top of the surface of the solar PV panel 2. This continuous and steady flowing water layer cools the solar PV panel and constantly removes dust and other foreign particles such as debris from the top surface of the solar PV panel. In addition, the flowing water layer collects additional solar irradiation due to light refraction. The debris and dust removal and the additional solar irradiation due to light refraction reduce the overall cost and complexity of the system design.

The additional solar irradiation due to light refraction created by various water flow patterns increases the energy harvest of the solar PV panel 2. In particular, the various water flow patterns may have different antireflection properties, i.e., the loss of electrical energy by reflection of the sun light on the top surface of the solar PV panel 2 may be reduced by reducing the amount of reflected sun light or by at least partially guiding sun light back to the top surface of the solar PV panel 2 within the water layer. The water flow control structure 105 is configured to generate or create the various water flow patterns.

Depending on the temperature of the solar PV panel 2, on the amount of dust or foreign particles to be removed, on the angle through which the sun light arrives at the solar PV panel, or on any other factors, the water flow pattern may be changed using the water flow control structure 105. In a preferred embodiment, the water flow control structure 105 is built into the panel mounting structure 1. No valves are required to control the water flow. This reduces the probability of equipment failures and the need for future maintenance, i.e., it reduces the (O&M) costs.

If the temperature of the solar PV panel 2 is too high, the amount of water per time unit provided on the surface of the solar PV panel 2 may be increased. Depending on the angle through which the sun light arrives at the solar PV panel, the shape of the water layer surface may be changed from a continuous and steady water layer surface to a rough or discontinuous water layer surface. This provides great flexibility in the flow patterns.

While the present invention has been particularly shown and described with reference to exemplary embodiments thereof, it will be understood by those skilled in the art that various changes in form and details may be made therein without departing from the spirit and scope of the invention.

What is claimed is:

1. A solar photovoltaic panel system comprising:
a thermal sink comprising a water source;
a panel mounting structure comprising:
a water flow section comprising an inflow section and an outflow section;
at least one solar photovoltaic panel mounted between the inflow section and the outflow section; and
a water supply system operated by hydropower, connected to the panel mounting structure and configured to provide water to the inflow section from the thermal sink,
wherein the water flows on a surface of the at least one solar photovoltaic panel and is returned to the thermal sink.

2. The solar photovoltaic panel system of claim 1, further comprising:
a vertical structure comprising a first end and a second end;
a base plate attached to the first end of the vertical structure;
a water flow section attached to the second end of the vertical structure;
a first mounting bracket attached to a portion of the vertical structure; and
an inflow panel mounting structure attached to the first mounting bracket in which a first end of the at least one solar photovoltaic panel is mounted.

3. The solar photovoltaic panel system of claim 1, wherein the inflow section comprises:
an inflow water channel structure attached to the second end of the vertical structure;
a water flow control structure to control a flow of water on a top surface of the at least one solar photovoltaic panel, the water flow control structure comprising a water outlet, and the water flow control structure being connected to the inflow water channel structure;
an inflow channel debris guard, integrated in the inflow water channel structure;
an inflow end cap provided at an end of the inflow water channel structure, and
a water inlet connected to the inflow water channel structure.

4. The solar photovoltaic panel system of claim 1, wherein the outflow section comprises:
an outflow water channel structure;
a second mounting bracket attached to the outflow water channel structure; and
a panel mounting section,
wherein the panel mounting section is attached to the second mounting bracket in which a second end of the at least one solar photovoltaic panel is mounted.

5. The solar photovoltaic panel system of claim 4, wherein the outflow water channel structure is attached to another vertical structure comprising another base plate.

6. The solar photovoltaic panel system of claim 1, wherein the water supply system is operated without consuming electrical energy.

7. The solar photovoltaic panel system of claim 6, wherein the water supply system comprises a ram pump.

8. The solar photovoltaic panel system of claim 1, wherein the water supply system comprises:
a pump;
a filter; and
a pipe connecting the pump with the vertical structure, with the filter, and with the water source.

9. The solar photovoltaic panel system of claim 8, wherein the filter comprises a primary filter and a secondary filter, and
wherein the primary filter is installed in the water source.

10. The solar photovoltaic panel system of claim 8, wherein the pump comprises a ram pump.

11. The solar photovoltaic panel system of claim 3, wherein the panel mounting structure comprises an internal pipe which connects the water supply system with the water inlet.

12. The solar photovoltaic panel system of claim 3, wherein the water flow control structure is a valveless structure and configured to control the flow of water on a top surface of the at least one solar photovoltaic panel to be a continuous flow of water.

13. The solar photovoltaic panel system of claim 1, wherein the water source comprises a river, a lake, a marina, or an ocean.

14. The solar photovoltaic panel system of claim 1, further comprising:
at least one water collection tray provided between two adjacent solar photovoltaic panels of the at least one solar photovoltaic panel and configured to collect water that flows into a gap between the two adjacent solar photovoltaic panels.

15. The solar photovoltaic panel system of claim 14, wherein the at least one water collection tray is attached to some portion of the water flow section.

16. The solar photovoltaic panel system of claim 1, further comprising:
at least one water collection tray attached to a side of the at least one solar photovoltaic panel which is not adjacent to another solar photovoltaic panel.

17. The solar photovoltaic panel system of claim 4, wherein the outflow section further comprises an outflow section outlet,
wherein the photovoltaic panel system further comprises a return water channel,
wherein a first end of the return water channel is connected to the outflow section outlet and a second end of the return water channel returns water to the thermal sink.

18. The solar photovoltaic panel system of claim 4, wherein the outflow section further comprises an outflow end cap provided at an end of the outflow water channel structure; and
an outflow channel debris guard attached to the outflow water channel structure,
wherein the return water channel comprises a return pipe.

19. The solar photovoltaic panel system of claim 3, wherein the flow of the water is controlled by the water flow control structure to provide a water flow pattern on the top surface of the at least one solar photovoltaic panel that increases the energy harvest of the at least one solar photovoltaic panel by capturing additional solar irradiation on the top surface of the at least one solar photovoltaic panel due to light refraction.

20. The solar photovoltaic panel system of claim 19, wherein the water flow control structure comprises an adjustable water flow bracket, an adjustable spacer, and a fastener.

21. The solar photovoltaic panel system of claim 20, wherein the water flow bracket and the spacer are adjusted by an electric step motor which is controlled by a controller.

22. The solar photovoltaic panel system of claim 3, wherein the water flow control structure comprises at least one nozzle configured to spray the water on the top surface of the at least one solar photovoltaic panel.

23. The solar photovoltaic panel system of claim 1, wherein the outflow section is provided at a position that is lower than a position of the inflow section.

24. A method for treating a solar photovoltaic panel comprising:
mounting at least one solar photovoltaic panel between an inflow section and an outflow section of a panel mounting structure;
connecting a water supply system operated by hydropower to the panel mounting structure to provide water from a thermal sink which comprises a water source;
providing a flow of water on a surface of the solar photovoltaic panel; and
returning the water to the thermal sink.

25. The method for treating a solar photovoltaic panel of claim 24, further comprising:
controlling the flow of water on the top surface of the at least one solar photovoltaic panel by a water flow control structure comprising a water outlet.

26. The method for treating a solar photovoltaic panel of claim 25, wherein the water flow control structure comprises at least one nozzle configured to spray the water on the top surface of the at least one solar photovoltaic panel.

27. A solar photovoltaic panel system comprising:
a thermal sink comprising a water source;
a panel mounting structure comprising:
a water flow section comprising an inflow section and an outflow section;
at least one solar photovoltaic panel mounted between the inflow section and the outflow section; and
a water supply system operated by electric power, connected to the panel mounting structure and configured to provide water to the inflow section from the thermal sink,
wherein the water flows on a surface of the at least one solar photovoltaic panel and is returned to the thermal sink.

28. The solar photovoltaic panel system of claim 27, wherein the water supply system comprises an electric pump.
